(19) United States
(12) Patent Application Publication
(10) Pub. No.: US 2006/0061426 A1
(43) Pub. Date: Mar. 23, 2006

(54) Method and circuit for suppressing oscillation modes in ring oscillators

(76) Inventors: Reiner Bidenbach, Vostetten (DE); Ulrich Theus, Gundelfingen (DE); Wilfried Gehrig, March (DE)

Correspondence Address: O'Shea, Getz & Kosakowski, P.C., Suite 912, 1500 Main Street, Springfield, MA, 01115, US

(21) Appl. No.: 11/234,402

(22) Filed: Sep. 23, 2005

(30) Foreign Application Priority Data
Sep. 23, 2004 (DE) 10 2004 046 519.3

(51) Int. Cl. H03K 3/03

(52) U.S. Cl. 331/57

(57) ABSTRACT

To suppress oscillation modes, in particular, higher-order oscillation modes, in a ring oscillator comprising delay elements forming the oscillator ring and being linked by nodes in the ring, and further comprising a gate element located in the oscillator ring which is activated by a control signal to open and close the gate element, the control signal is derived from at least one of the levels of the oscillator signal at the nodes. The control signal is such that the normal oscillation mode, that is, the fundamental oscillation and/or another desired higher-order oscillation, is not affected by the gate. However, unwanted oscillation modes (e.g., the higher oscillation modes) are effectively suppressed in the case of the fundamental oscillation representing the normal oscillation mode.

### PRIORITY INFORMATION

This patent application claims priority from German patent application 10 2004 046 519.3 filed Sep. 23, 2004, which is hereby incorporated by reference.

### BACKGROUND OF THE INVENTION

The invention relates in general to oscillators and in particular to a method and circuit for suppressing oscillation modes, in particular, higher-order oscillation modes, in a ring oscillator.

Long ring oscillators are employed in a number of areas, for example, to obtain different signal phase positions. The term “long” as used herein in general means that more than three delay elements are utilized within the ring oscillator. FIG. 3 illustrates a prior art ring oscillator 10 comprising a number n of delay elements T 12, the inputs of which are linked through corresponding nodes 14 to the outputs of the respective preceding delay elements 12 in the ring 10.

If the fundamental oscillation frequency of the ring oscillator 10 is variable, then controllable delay elements 12 may be employed within its delay period. If the delay period can be varied by a control voltage, a varactor- or voltage-controlled oscillator (VCO) may generate a fundamental oscillation which is phase-locked to a supplied reference signal, and the VCO is embedded in a phase-locked loop (PLL).

A signal having a predefined phase position can be sensed at each delay element 12. To ensure relatively high symmetry and thus relatively low deviation of the phase positions from their desired values, the delay elements 12 and their nodes 14 are typically implemented with a relatively high degree of similarity.

During the switching-on period of the control voltage, the inputs and outputs of the delay elements 12 have an undefined state. When the control voltage attains a predefined value, the delay elements 12 begin to operate normally. That is, the output signal is derived from the input signal after a time delay. For example, the output signal of a delay element 12 may represent the inverted input signal of that element. Due to the undefined state for the delay elements 12 during the switching-on period, many dynamic signal transitions are propagated. This means that at many points within the oscillator ring 10 the input level of the delay elements 12 does not result until after a delay in a change in the corresponding output level provided thereto.

In ideal systems, this undefined state would last indefinitely. In actual systems with analog delay elements 12, the leading transitions result in a situation in which the trailing transitions have a somewhat shorter propagation time through the delay elements 12. This situation is due to the finite internal resistance at which the electrical input and output nodes 14 are recharged. This internal resistance causes the voltage difference of the two different end states of a trailing transition to be smaller, with the result that the outputs of the delay elements 12 can change their states more quickly. As a result, after a few cycles within the oscillator ring 10 a trailing transition overtakes the leading transition and is then cancelled along with the latter (i.e., a “suction effect”). This continues until one transition still exists within the ring 10. This is the case for ring oscillators having an uneven number of inverting delay elements.

However, in actual oscillator rings there may be coupling effects that counteract the motion of the transitions toward each other. In this case, the above-described acceleration effect for trailing transitions predominates only in a limited number of successive delay elements.

As a result, an uneven number of transitions greater than one are maintained within the oscillator ring 10. This results in an uncertain number of frequencies or phase positions at the output of the delay elements 12. A detailed treatment of the above-described phenomena is found, for example, in the contributions by Yasuo Arai, entitled “TMC304 (TMC-TEG3) Trouble Report” dated Apr. 22, 1996 and May 31, 1996 in KEK Research Japan (National High Energy Accelerator Research Organisation), pages 1 to 8.

This problem can be counteracted following the teaching from “Ring Oscillator Design, Test and Applications” in Keithley Waferline, Summer 2000, pages 2 to 5, by inserting a gate element in the oscillator ring, where the gate element supplies at its output a predefined level independent of the input. Referring to FIG. 2, a prior-art ring oscillator 20 comprises delay elements T 22 linked through nodes 24 and further comprises a combined delay/gate element 26.

After reaching the operating voltage necessary to function, the combined delay/gate element 26 may be opened, and the output level changes as a function of the input. This approach may be feasible when a corresponding control signal on a line 28 is provided by a gate control device 30 to the delay/gate element 26.

A known approach is to generate an external control signal using a comparator that compares the operating voltage of the ring oscillator with a reference voltage at which all the delay elements within the ring oscillator are functional.

Although this type of activation of the gate element within the ring oscillator has been successful, this approach does not necessarily eliminate all of the unwanted oscillation modes, in particular, higher-order modes, during operation—for example, those resulting from interfering effects such as fluctuations in the operating voltage, and high-frequency or radioactive radiation.

What is needed is a technique for suppressing unwanted oscillation modes in ring oscillators.

### SUMMARY OF THE INVENTION

To suppress oscillation modes, in particular, higher-order oscillation modes, in a ring oscillator comprising delay elements forming the oscillator ring and being linked by nodes in the ring, and further comprising a gate element located in the oscillator ring which is activated by a control signal to open and close the gate element, the control signal is derived from at least one of the levels of the oscillator signal at the nodes. The control signal is such that the normal oscillation mode, that is, the fundamental oscillation and/or another desired higher-order oscillation, is not affected by the gate. However, unwanted oscillation modes (e.g., the higher oscillation modes) are effectively suppressed in the case of the fundamental oscillation representing the normal oscillation mode.

The gate element may be activated by the control signal to open the gate element when the levels applied at a number of predetermined nodes have a specific predetermined logical state, typically either a logic “high” or logic “low”. Unwanted states may be associated with unwanted oscillation modes, with the result that oscillation continues when desired states or oscillation modes are “handed over.”

Alternatively, the gate element may be opened by the control signal when the levels applied at a number of predetermined nodes following each other at regular intervals (e.g., equal intervals) have a specific predetermined logical state (high or low). In this variant, the number and type of oscillations that may occur can be predetermined in a relatively simple manner, for example when using oscillators with a relatively high degree of symmetry.

The number and selection of nodes or levels that are monitored and utilized to generate the control signal may depend, for example, on the type and number of the oscillation modes desired or to be filtered out.

To suppress higher-order oscillation modes, the specific predetermined logical states (high or low) are selected to be identical for all of the number of predetermined nodes. Specifically, this is done for all of the number of nodes following each other at regular intervals, for example, for all of the number of nodes following each other at equal intervals or for all of the number of nodes immediately following each other.

To keep the number of monitored nodes relatively small, the number of predetermined nodes selected may be smaller than the total number of nodes. The predetermined nodes may also be selected such that the levels of non-predetermined nodes are not able to assume an unpredictable logical state.

To generate the fundamental oscillation, the predetermined nodes may be selected such that on a sequence of successive non-predetermined nodes no two level transitions from one logical state (high or low) to another logical state (high or low) can form permanently.

These and other objects, features and advantages of the present invention will become more apparent in light of the following detailed description of preferred embodiments thereof, as illustrated in the accompanying drawings.

### BRIEF DESCRIPTION OF THE DRAWINGS

FIG. 1 illustrates a ring oscillator with an automatic gate control;

FIG. 2 illustrates a prior art ring oscillator having a gate element to prevent unwanted oscillations; and

FIG. 3 illustrates a prior art ring oscillator having inverting delay elements.

### DETAILED DESCRIPTION OF THE INVENTION

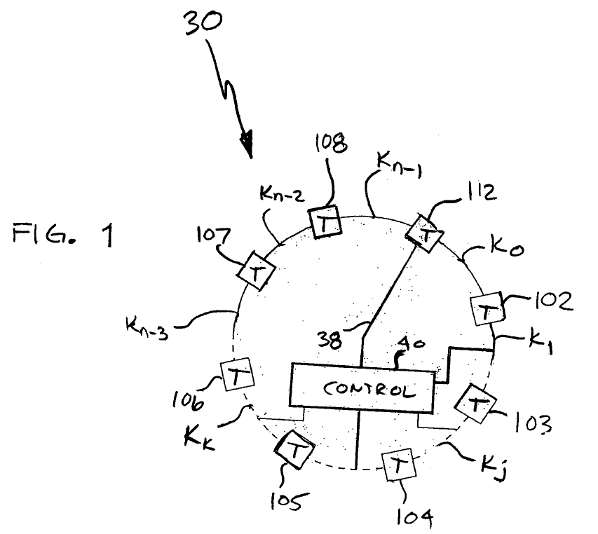

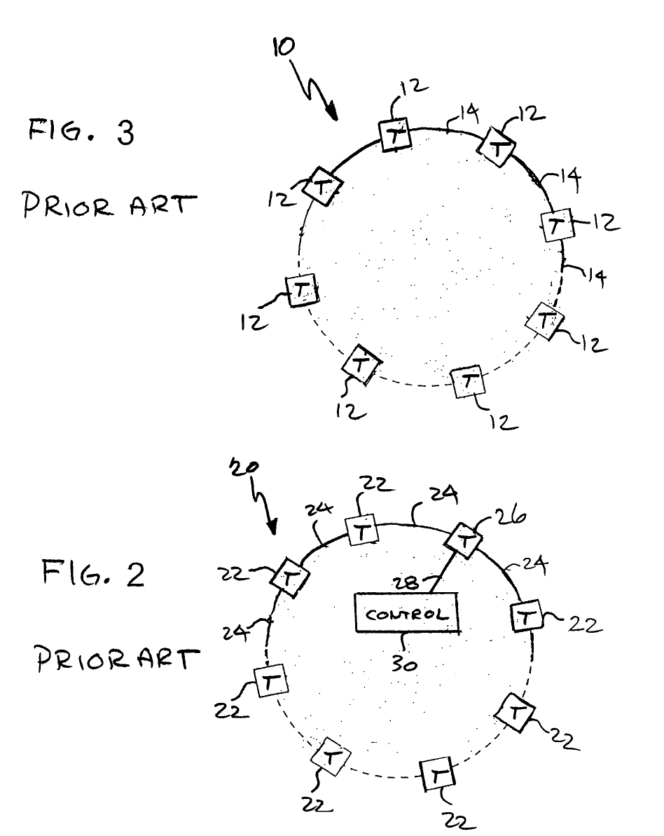

Referring to FIG. 1, a ring oscillator 30 includes a plurality of, for example, inverting delay elements T 102-108 linked through nodes K₀, K₁, . . . Kⱼ . . . Kₖ . . . Kₘ . . . Kₙ₋₁. The oscillator 30 also includes a delay/gate element 112 which may be activated by a control signal on a line 38 to open or close the delay/gate element 112. A gate control device 40 provides the control signal on the line 38 to the delay/gate element 112. The gate control device 40 may derive the control signal from the multiple levels of the oscillator signal applied at the various nodes K₀, K₁, . . . Kⱼ . . . Kₖ . . . Kₘ . . . Kₙ₋₁.

In describing the derivation of control signal on the line 38 to suppress higher-order oscillation modes (outside the fundamental mode) from the levels applied at the nodes, the beginning of the ring 30 refers to the output of the delay/gate element 112 or any location within the oscillator ring 30 without a gate element. The end of the ring 30 refers to the input of the delay/gate element 112, or the input of another one of the delay elements 102-108, the output of which is the beginning of the ring 30. State A refers to the state of the outputs and inputs of the individual delay elements 102-108 when the beginning and the end of ring 30 are in the logical “high” state and the fundamental mode is present in the ring oscillator 30. State B refers to the state of the outputs and inputs of individual delay elements 102-108 when the beginning and the end of the ring 30 are in the logical “low” state and the fundamental mode is present in the ring oscillator 30. Node Kₘ refers to the input of delay element Vₘ, which is equivalent to the output of the delay element Vₘ₋₁ for all m>=1.

Thus, in the fundamental mode either all the nodes K₀, K₁, . . . Kⱼ . . . Kₖ . . . Kₘ . . . Kₙ₋₁ have the same state (A or B), or there is one block of successive nodes Kⱼ . . . Kₖ that have state A and one block of successive nodes that have state B. If all the nodes Kₒ, K₁, . . . Kⱼ . . . Kₖ . . . Kₘ . . . Kₙ₋₁ have state A, then node K₀ after a delay receives state B. State B then carriers on with one delay after another to all the subsequent nodes K₁, . . . Kⱼ . . . Kₖ . . . Kₘ . . . Kₙ₋₁. Once state B has reached node Kₙ₋₁, all the nodes K₀, K₁, . . . Kⱼ . . . Kₖ . . . Kₘ . . . Kₙ₋₁ have state B. After a delay, node K₀ reassumes state A and this state propagates analogously.

If a higher oscillation mode exists within the oscillator ring, then at no time do all the nodes K₀, K₁, . . . Kⱼ . . . Kₖ . . . Kₘ . . . Kₙ₋₁ have the same state.

In the fundamental mode, there is thus no disturbing effect of setting node K₀ to state A (independently of the state of node Kₙ₋₁) until all the nodes up to a predetermined node Kₖ have assumed state A, and only when this condition is met again making node K₀ dependent on node Kₙ₋₁. If the value n-1 is selected for k, then no higher oscillation mode is able to propagate. This is due to the fact that all of the nodes are forced to assume state A. This then immediately induces the fundamental mode.

In practice, k is chosen to be somewhat smaller so that the delay of gate element T alone acts on the signal, and not any delays of the monitoring circuit.

The value of k is selected to be large enough such that in no case can two transitions form permanently on the remaining non-monitored section up to the end of ring 30. For the same reason, it is also not necessary to monitor all the nodes K₀, K₁, . . . Kⱼ . . . Kₖ of the range from 0 to k for state A. Instead, it suffices to monitor every 2^{nd} or 3^{rd} or i^{th} node, depending on the range of the above-described suction effect. The beginning of the monitored range also may not be node K₀; it may also be node Kⱼ. As such, it is practical to ensure that no two transitions can form in the non-monitored range from k to j.

Instead of state A, it may also be possible to monitor state B.

Although the present invention has been illustrated and described with respect to several preferred embodiments thereof, various changes, omissions and additions to the form and detail thereof, may be made therein, without departing from the spirit and scope of the invention.

What is claimed is:

1. A method for suppressing oscillation modes in a ring oscillator having delay elements linked through corresponding nodes and including a gate element, comprising the steps of:
activating the gate element by a control signal to open and close the gate element during a time period to suppress the oscillation modes; and
deriving the control signal from a logic level of an oscillator signal applied at the nodes.

2. The method of claim 1, where the step of activating the gate element by the control signal is performed when the level applied on at least one predetermined node comprises a predetermined logical state.

3. The method of claim 1, where the step of activating the gate element by the control signal is performed when the level applied at a plurality of predetermined nodes following each other at regular intervals comprises a predetermined logical state.

4. The method of claim 1, where the step of activating the gate element by the control signal is performed when the level applied at a plurality of predetermined nodes following each other at equal intervals comprises a predetermined logical state.

5. The method of claim 1, where the step of activating the gate element by the control signal is performed when the level applied at a plurality of predetermined nodes immediately following each other comprises a predetermined logical state.

6. The method of claim 1, where the step of activating the gate element by the control signal is performed when the level applied on each of a plurality of predetermined nodes comprises a predetermined logical state.

7. The method of claim 6, where the predetermined logical state comprises the same logical state for all of the plurality of predetermined nodes.

8. The method of claim 7, where the predetermined logical state comprises the same logical state for all of the plurality of predetermined nodes following each other at regular intervals.

9. The method of claim 7, where the predetermined logical state comprises the same logical state for all of the plurality of predetermined nodes following each other at equal intervals.

10. The method of claim 7, where the predetermined logical state comprises the same logical state for all of the plurality of predetermined nodes immediately following each other.

11. The method of claim 6, where the plurality of predetermined nodes comprises a number of the nodes that is smaller than a total number of all of the nodes in the ring oscillator.

12. The method of claim 6, where each of the plurality of predetermined nodes assumes a predictable logical state.

13. A ring oscillator that suppresses oscillation modes within the ring oscillator, comprising:
a plurality of delay elements;
a plurality of nodes linking the delay elements;
a gate element being activated by a control signal to open and close the gate element at predetermined times; and
a gate control device that derives the control signal from at least one of the levels of an oscillator signal applied at the plurality of nodes.

14. The ring oscillator of claim 13, where the gate control device activates the gate element with the control signal to open the gate element when the levels applied at a predetermined number of the plurality of nodes have a predetermined logical state.

15. The ring oscillator of claim 13, where the gate control device activates the gate element with the control signal to open the gate element when the levels applied at a predetermined number of the plurality of nodes following each other at regular intervals have a predetermined logical state.

16. The ring oscillator of claim 13, where the gate control device activates the gate element with the control signal to open the gate element when the levels applied at a predetermined number of the plurality of nodes following each other at equal intervals have a predetermined logical state.

17. The ring oscillator of claim 13, where the gate control device activates the gate element with the control signal to open the gate element when the levels applied at a predetermined number of the plurality of nodes immediately following each other have a predetermined logical state.

18. The ring oscillator of claim 14, where the predetermined logical state comprises the same logical state for all of the predetermined number of the plurality of nodes.

19. The ring oscillator of claim 14, where the predetermined logical state comprises the same logical state for all of the predetermined number of the plurality of nodes following each other at regular intervals.

20. The ring oscillator of claim 14, where the predetermined logical state comprises the same logical state for all of the predetermined number of the plurality of nodes following each other at equal intervals.

21. The ring oscillator of claim 14, where the predetermined logical state comprises the same logical state for all of the predetermined number of the plurality of nodes immediately following each other.

22. The ring oscillator of claim 13, where the plurality of predetermined nodes comprises a number of the nodes that is smaller that the total number of all of the nodes in the ring oscillator.

23. The ring oscillator of claim 13, where each of the plurality of nodes assumes a predictable logical state.
